(19) United States
(12) Patent Application Publication
(10) Pub. No.: US 2008/0094874 A1
(43) Pub. Date: Apr. 24, 2008

(54) Multiple-read resistance-variable memory cell structure and method of sensing a resistance thereof

(75) Inventor: Jhon Jhy Liaw, Hsin-Chu (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu City (TW)

(21) Appl. No.: 11/552,084

(22) Filed: Oct. 23, 2006

(51) Int. Cl. G11C 11/00

(52) U.S. Cl. 365/148; 365/158; 365/163

(57) ABSTRACT

Disclosed herein is a multiple read-port nonvolatile memory cell structure, and related method of sensing a resistance state of memory cell, for high-speed and high-bandwidth applications. It provides about a 2× bandwidth gain over conventional cells during the read cycle in embodiments where two read ports are constructed. For example, where conventional arrays include only one read wordline and one read bitline for each memory cell in an array, an array constructed as disclosed herein includes at least two read wordlines and at least two read bitlines for each memory cell. It is still comparable in cell size with a typical 1T1RV cell because the cell pitch is limited by backend size and under-metal layer connection layout.

### TECHNICAL FIELD

Disclosed embodiments herein relate generally to resistance-variable (RV) nonvolatile memory cells, and more particularly to systems and methods for a multiple-read RV memory cell structure.

### BACKGROUND

Magnetic random access memory (MRAM) is a type of non-volatile memory that uses magnetism rather than electrical power to store data. Key attributes of MRAM technology are nonvolatility and unlimited read and program endurance. A fundamental issue for magnetic, resistance-variable (RV) memory cells, such as MRAM cells, is the sensing scheme for reading data from a Magnetic Tunneling Junction (MTJ) element within a memory cell.

Conventional schemes have several limitations and drawbacks. One such limitation that affects device performance is the speed in reading data from the memory cells. Currently, logic circuits are operating at frequencies in the GHz ranges. However, conventional MRAM read schemes are constrained to operate at much slower rates, causing a significant performance gap between the logic circuits and the MRAM memory. This performance gap results in a suboptimal performance of the logic circuits because supporting MRAM memory devices cannot provide data and instructions fast enough. Thus, this results in a bottleneck effect at the MRAM devices, particularly in System on Chip (SoC) designs, which combine memory with logic circuitry on a chip.

Thus, sensing the resistance state of a resistance-variable memory cell can be detrimental to the overall performance of the device incorporating the memory cells. It would therefore be desirable to more quickly sense the resistance states of memory cells, such as in MRAM devices, in order to improve the speed of memory cells data read access.

### BRIEF SUMMARY

Disclosed herein is a multiple read-port nonvolatile memory cell structure, and related method of sensing a resistance state of memory cell, for high-speed and high-bandwidth applications. It provides about a 2× bandwidth gain over conventional cells during the read cycle in embodiments where two read ports are constructed. For example, where conventional arrays include only one read wordline and one read bitline for each memory cell in an array, an array constructed as disclosed herein includes at least two read wordlines and at least two read bitlines for each memory cell. As for cell size, it is still comparable with a typical 1T1RV cell because the cell pitch is limited by backend size and under metal layer connection layout.

In one embodiment, a multiple read-port resistance-variable memory cell structure is provided. In one such embodiment, the memory cell structure comprises a resistance-variable element having conductive first and second electrodes, and a resistance-variable structure between the electrodes that is capable of being switched between a high resistance state and a low resistance state. The cell structure further comprises a first conductor electrically coupled to the first electrode and laying in a first direction, and at least two second conductors electrically coupled from the second electrode to at least one sensing device for sensing a resistance of the resistance-variable element. In this embodiment, the cell structure also includes at least two switching elements electrically coupled between corresponding ones of the second conductors and the at least one sensing device. Further, such a cell structure includes at least two third conductors coupled to and configured to activate corresponding ones of the at least two switching elements to switch the resistance-variable element between the high and low resistance states.

Also disclosed herein is a method for sensing a resistance state of a resistive-variable memory cell, where the cell has a resistance-variable element comprising first and second electrodes and a resistance-variable structure between the electrodes capable of being switched between a high resistance state and a low resistance state. In one embodiment, the method comprises providing a read signal to a first conductor electrically coupled to the first electrode and laying in a first direction. In addition, the method includes providing a corresponding activation signal to at least one of at least two switching elements electrically coupled between corresponding at least two second conductors that are coupled to the second electrode and at least one sensing device. Moreover, in this embodiment the method includes detecting the resistance state of the resistance-variable element with the at least one sensing device based on the read signal passing through the resistance-variable element, through a corresponding second conductor, and through the activated at least one switching element.

### BRIEF DESCRIPTION OF THE DRAWINGS

For a more complete understanding of the principles disclosure herein, and the advantages thereof, reference is now made to the following descriptions taken in conjunction with the accompanying drawings, in which:

FIG. 1 illustrates a schematic block diagram of an MRAM memory cell and reference cells coupled to a sense amplifier in accordance with the present disclosure;

FIG. 2 illustrates a schematic diagram of an exemplary MRAM memory cell and reference cells coupled to a sense amplifier in accordance with the present disclosure;

FIG. 3 illustrates a schematic block diagram of a typical magnetic tunneling junction (MTJ) structure in accordance with the present disclosure;

FIG. 4 shows a graph of the relationship between resistance and the relative magnetic orientations of the free and pinned layers in the MTJ shown in FIG. 3;

FIG. 5 illustrates an MRAM array having a plurality of MRAM cells constructed according to the disclosed principles;

FIG. 6 illustrates one embodiment of a one-write, two-read resistance-variable cell constructed according to the disclosed principles;

FIG. 6A illustrates one embodiment of a one-write, two-read PRAM cell constructed according to the disclosed principles; and

FIG. 7 illustrates one embodiment of an MRAM cell constructed according to the disclosed principles.

### DETAILED DESCRIPTION

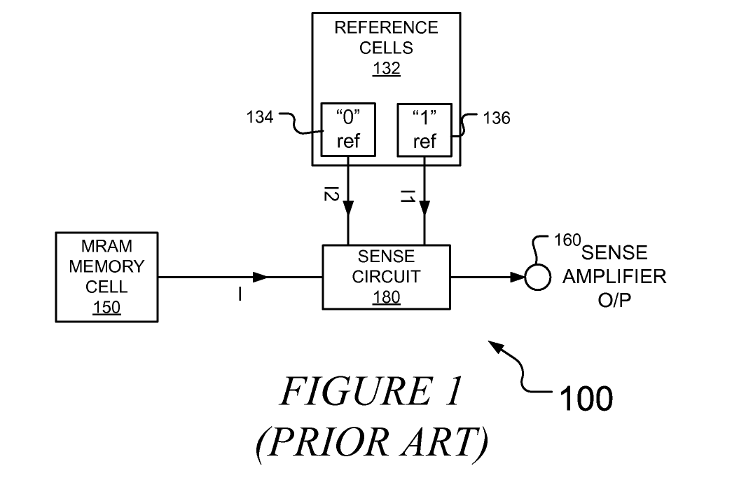

FIG. 1 shows a schematic diagram of a portion 100 of a conventional MRAM array, which includes an MRAM memory cell 150, a single sense amplifier 180, and a single set of reference cells 132, operably coupled as shown. MRAM memory cell 150 has a high resistance state and a low resistance state, depending on whether the cell 150 is configured with a high or low logical state of data. The reference cells 132 include a low (“0”) reference cell 134, which is configured with a low resistance state, and a high (“1”) reference cell 136, which is configured with a high resistance state.

Generally, the sense amplifier 180 determines the binary logic state of data stored in MRAM memory cell 150 by comparing an output current (I) from the MRAM memory cell 150 with a first reference current (I1) from high reference cell 136 and a second reference current (I2) from low reference cell 134. First reference current (I1) is representative of the resistance of a memory cell storing data with the high resistance state. Likewise, second reference current (I2) is representative of the resistance of a memory cell storing data with the low resistance state. The output current, first, and second reference currents may be generated by applying a predetermined voltage to the memory cell 150 and the reference cells 132. Sense amplifier 180 compares output current with the first and second reference currents to determine the resistance state of the MRAM cell 150, and provides an output signal at the sense amplifier output 160 indicating a logic-low or logic-high state of data stored in the MRAM memory cell 150.

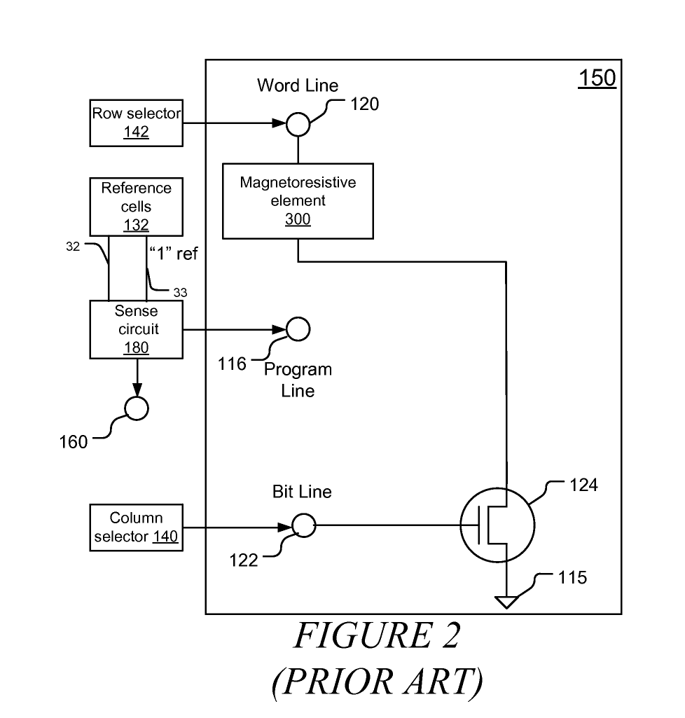

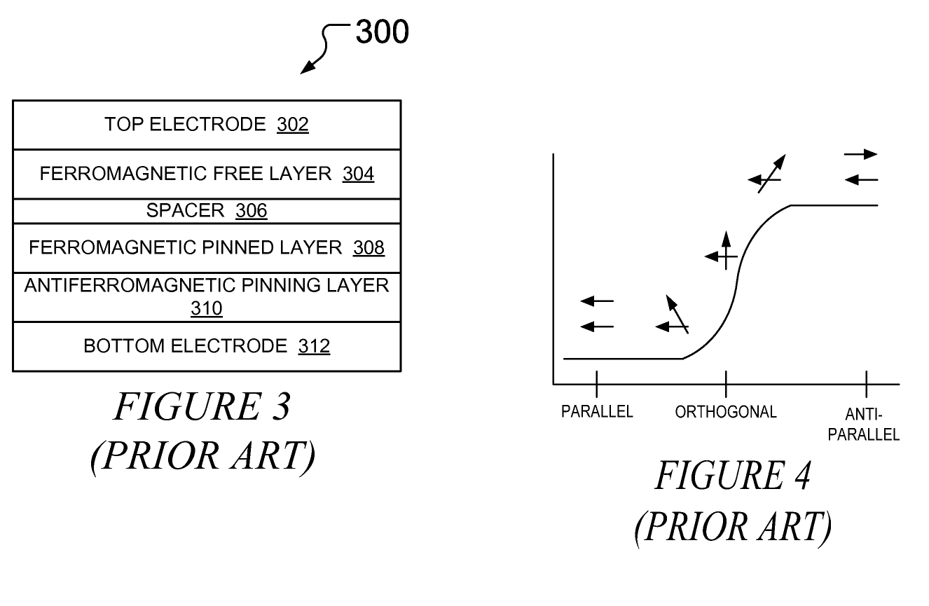

FIG. 2 shows a schematic diagram of a portion 100 of an MRAM array, which includes the exemplary MRAM memory cell 150, the single sense circuit 180, the reference cells 132, a single column selector 140, and a single row selector 142, operably coupled as shown in the figure. The memory cell 150 includes a magnetoresistive (e.g., magnetic-tunneling-junction or “MTJ”) element 300, and a single reference transistor 124. Sense circuit 180 may be selectively coupled to the memory cell 150 via program line 116. The MTJ element 300 can include layers 302-312 shown in FIG. 3 and further described with reference to FIG. 4 below.

Exemplary MRAM memory cell 150 provides reference transistor 124 having a gate node coupled to a bit line (BL) 122, a source node coupled to either a predetermined voltage V_{DD} or a signal ground V_{SS} at 115 (depending on the transistor type used), and a drain node coupled to the bottom electrode (312 in FIG. 3) of the MTJ element 300. The top electrode (302 in FIG. 3) of the MTJ element 300 is coupled to a word line (WL) 120. The program line 116 may extend in the vicinity of the MTJ element 300 for write operations. Alternatively, or in addition, a current may be provided to a write line (not shown) to perform a write operation to the MTJ element 300. The column and row selectors 140, 142 are used for addressing cells of the MRAM array 100. For this purpose, the column selector 140 controls the voltage level of the BL 122 and the row selector controls the voltage level of the WL 120.

As mentioned above, the sense circuit 180 detects the logic state of the memory cell 150 based on a comparison of the current on the program line 116 to high and low reference currents received from the reference cells 132.

During a write operation, electrical current flows through program line 116 and a current is passed through WL 120. The magnitude of these currents is selected such that, ideally, the resulting magnetic fields are not strong enough to affect the memory state of other proximate MR elements in the array, yet the combination of the two magnetic fields (at MTJ element 300) is sufficient for switching the memory state (e.g., switching the magnetic moment of the free layer 304 shown in FIG. 3). In another embodiment (not shown) a dedicated write line may be used. For example, a write operation may be performed by passing electrical current through a bit write line, that extends in the same direction as program line 116. Bit write line is proximate to the bottom electrode (312 of FIG. 3) and is orthogonal to WL 120. The above descriptions regarding the writing and reading of data in MRAM cells is typical of conventional arrays of MRAM or other types of resistance-variable cells. In contrast, the novel structure and related technique for reading data from such cells employs a greater number of wordlines and bitlines than these conventional structures, and is described in greater detail below.

FIG. 3 shows an example of a typical MTJ element 300, which may be used in an MRAM cell when the memory array employs MRAM resistance-variable components. While employing the disclosed concept with MRAM arrays is extremely beneficial, it should be understood that the disclosed principles may also be employed with other types of non-volatile resistive variable components, such as PRAM cells.

The MTJ element 300 includes the following layers: a top electrode layer 302, a ferromagnetic free layer 304, a spacer 306 which serves as a tunneling barrier, a ferromagnetic pinned layer 308, an antiferromagnetic pinning layer 310, and a bottom electrode 312. The ferromagnetic free layer 304 and the ferromagnetic pinned layer 308 are constructed of ferromagnetic material, for example cobalt-iron or nickel-cobalt-iron. The antiferromagnetic pinning layer 310 is constructed of antiferromagnetic material, for example platinum manganese. Magnetostatic coupling between the ferromagnetic pinned layer 308 and the antiferromagnetic pinning layer 310 causes the ferromagnetic pinned layer 308 to have a fixed magnetic moment. The ferromagnetic free layer 304, on the other hand, has a magnetic moment that, by application of a magnetic field, can be switched between a first orientation, which is parallel to the magnetic moment of the ferromagnetic pinned layer 308, and a second orientation, which is antiparallel to the magnetic moment of the ferromagnetic pinned layer 308.

The spacer 306 interposes the ferromagnetic pinned layer 308 and the ferromagnetic free layer 304. The spacer 306 is composed of insulating material, for example aluminum oxide, magnesium oxide, or tantalum oxide. The spacer 306 is formed thin enough to allow the transfer (tunneling) of spin-aligned electrons when the magnetic moments of the ferromagnetic free layer 304 and the ferromagnetic pinned layer 308 are parallel. On the other hand, when the magnetic moments of the ferromagnetic free layer 304 and the ferromagnetic pinned layer 308 are antiparallel, the probability of electrons tunneling through the spacer 306 is reduced. This phenomenon is commonly referred to as spin-dependent tunneling (SDT).

As shown in FIG. 4, the electrical resistance through the MTJ element 300 (e.g., through layers 302-312) increases as the moments of the pinned and free layers become more antiparallel, and decreases as they become more parallel. In an MRAM memory cell, the electrical resistance of the MTJ element 300 can therefore be switched between first and second resistance values representing first and second logic states. For example, a high resistance value (antiparallel) can represent a logic state “1” and a low resistance value (parallel) can represent a logic state “0”. The logic states thus stored in the memory cells can be read by passing a sense current through the MR element and sensing the resistance.

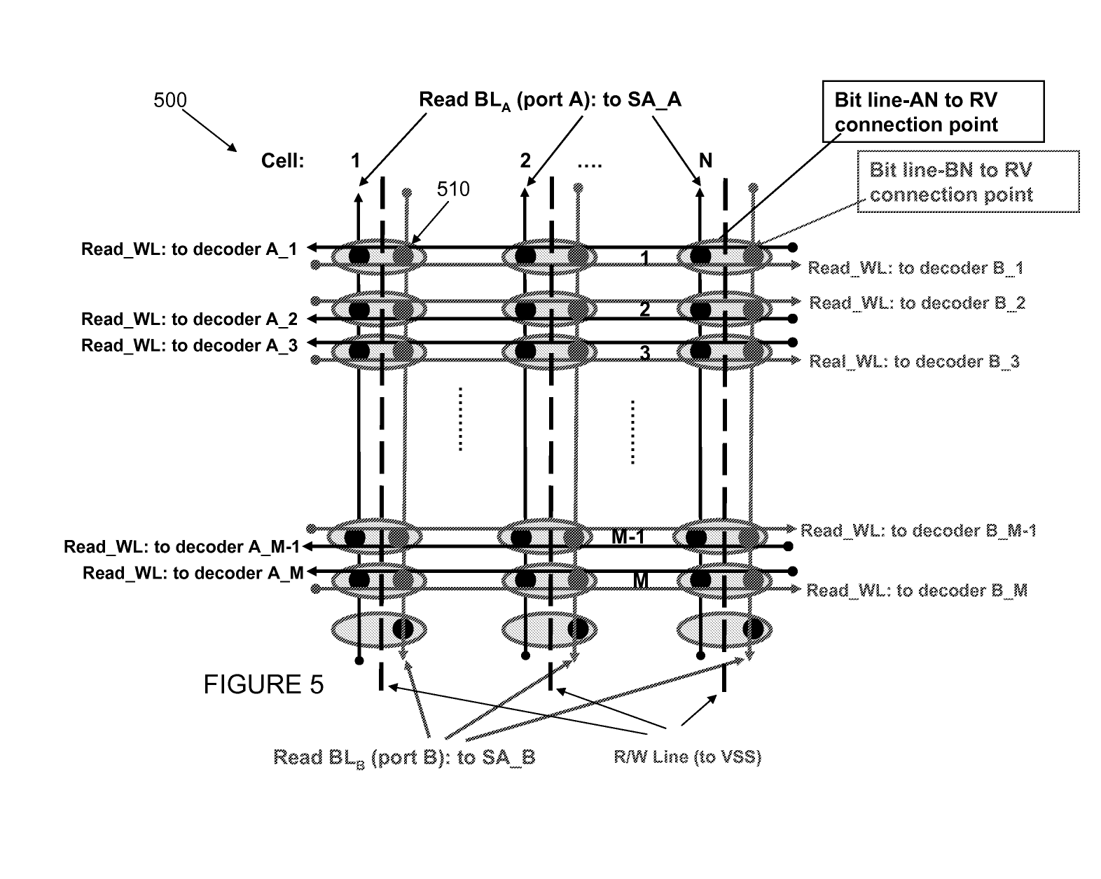

FIG. 5 illustrates an MRAM array 500 having a plurality of MRAM cells (one of which is labeled 510) as the desired resistance-variable memory cells, and which has been constructed according to the disclosed principles. As shown, the plurality of MRAM cells 510 are arranged in a predetermined number of columns (1, 2, . . . N), as well as in a predetermined number of rows (1, 2, 3, . . . M−1, M; where M is the maximum number of rows). Where conventional arrays include only one read wordline (Read_WL) and one read bitline (Read_BL) for each MRAM cell in an array, the array 500 constructed as disclosed herein includes two read wordlines and two read bitlines for each MRAM cell 510. A read/write (W/R Line) used for both and read and write operations in the array 500 is also illustrated.

Because two read wordlines and two read bitlines are employed in this structure, two sense amplifier circuits (or, alternatively, two sets of ports within a single sense amplifier) are employed with respective sets of wordlines and bitlines. Specifically, one set of read bitlines (Read_BL_{A1}, Read_BL_{A2}, . . . Read_BL_{AN}) may be electrically coupled to a first port (Port A) of a sense amplifier (SA_A; not illustrated). Then, a second set of read bitlines (Read_BL_{B1}, Read_BL_{B2}, . . . . Read_BL_{BN}) may be electrically coupled to a second port (Port B) of the same or a second sense amplifier (SA_B; not illustrated). Also, one set of read wordlines (Read_WL_{A1}, Read_WL_{A2}, . . . . Read_WL_{AM-1}, Read_WL_{AM}) may be electrically coupled to a first decoder's (not illustrated) corresponding nodes (A_1, A_2, A_3, . . . A_M−1, A_M). Similarly, a second set of read wordlines (Read_WL_{B1}, Read_WL_{B2}, . . . . Read_WLB_{M-1}, Read_WL_{BM}) may be electrically coupled to a second decoder's (not illustrated) corresponding nodes (B_1, B_2, B_3, . . . B_M−1, B_M).

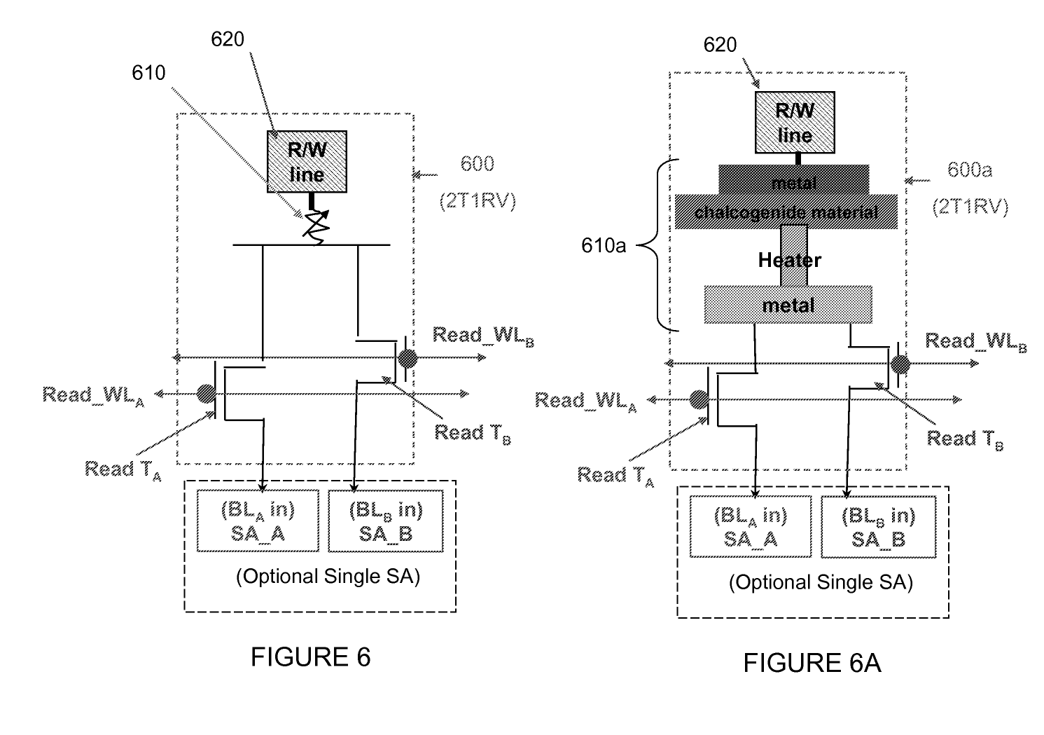

Turning now to FIG. 6, illustrated is a one-write, two-read resistance-variable cell 600 constructed according to the disclosed principles. The RV cell 600 includes a resistance-variable memory element 610, such as an MTJ for an MRAM cell or, in the case of the illustrated embodiment in FIG. 6A a phase-change structure for a PRAM cell 600a. If a PRAM cell 600a is employed, the RV element 600a will typically be comprised of a heater, chalcogen elements (e.g., chalcogenide material) and a metal layer covering the surface of the phase-change material layer opposite the substrate. In a more specific embodiment, the phase-change (i.e., the chalcogenide material) is a GST (Ge2Sb2Te5) base material, but the disclosed principles are broad enough to encompass other types of phase-change material. For example, the phase-change material may be comprised of Te, Se, Ge, Sb, Bi, Pb, Sn, As, S, Si, P, O, or any mixture or alloy thereof.

The RV cell 600 in FIG. 6 further includes two switching elements, which in this embodiment are pass transistors T_{A}, T_{B} (2T1RV). At least two transistors are provided by the disclosed principles, rather than a single pass transistor (1T1RV) as found in conventional RV cell structures. The first pass transistor T_{A} is coupled on a first bitline (BL_{A}) from the RV element 610 to a first sense amplifier SA_A. The second pass transistor T_{B} is coupled on a second bitline (BL_{B}) from the RV element 610 to a second sense amplifier SA_B. As before, the bitlines may alternatively be coupled to first and second ports on a single sense amplifier, and the disclosed structure is not limited to either embodiment. The RV cell 600 also includes a read/write (R/W) conductive line 620 coupled to the top electrode of the RV element 610 that is used in both the reading and writing of the RV element 610. The PRAM cell 600a in FIG. 6A includes a similar construction, as shown.

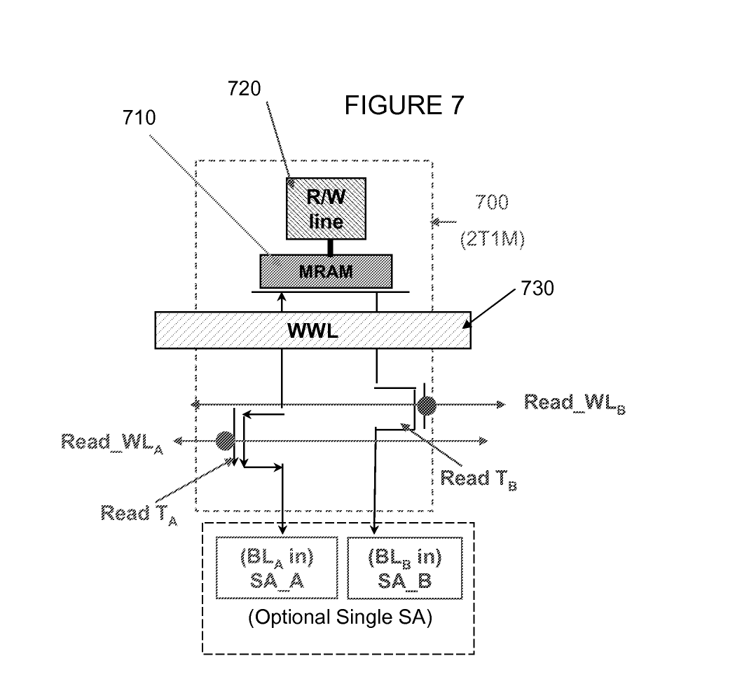

FIG. 7 illustrates a more specific embodiment of a resistance-variable cell 700 constructed according to the disclosed principles. The RV cell 700 includes a resistance-variable memory element 710 that is an MTJ for an MRAM cell. The MTJ stack of the MRAM element 710 may be of the type illustrated and discussed above. The MRAM cell 700 in FIG. 7 also includes two switching elements, which again are two pass transistors T_{A}, T_{B} (2T1MTJ), rather than a single pass transistor (1T1MTJ) as found in conventional MRAM cell structures. The first pass transistor T_{A} is again coupled on a first bitline (BL_{A}) from the MRAM element 710 to a first sense amplifier SA_A. Also as before, the second pass transistor T_{B} is coupled on a second bitline (BL_{B}) from the MRAM element 710 to a second sense amplifier SA_B. Of course, the bitlines may alternatively be coupled to first and second ports on a single sense amplifier, as discussed above.

The MRAM cell 700 also includes a read/write (R/W) conductive line 720 coupled to the top electrode of the MRAM element 710 that is again used in both the reading and writing of the MRAM element 710. In addition, because this embodiment is an MRAM cell 700, a write wordline (WWL) 730 is also included. As described in greater detail below, to establish the resistance state of the MRAM element 710 (a “write” operation), the write wordline 730 is used to provide a magnetic field proximate to the MRAM element 710, along with another magnetic field provided to the MRAM element 710 via a signal (e.g., current) on the R/W line 720. In exemplary embodiments, the WWL 730 is constructed orthogonal to the R/W line 720 so that orthogonal magnetic fields are applied to the MRAM element 710 (see FIG. 4).

What follows is a description of the typical read and write cycles for a conventional 1T1MTJ MRAM cell.

### Read Cycle:

(1) Read_WL is set to “High” (Transistor T1 is set to ON)

(2) Write_WL is set to OFF (“No function” or “floating”)

(3) R/W BL is set to ON with a voltage (0.3V˜1.2V)

(4) Sense amplifier connected to BL senses resistance of MTJ for data read

### Write (Program) Cycle:

(1) Write_WL is set to “High”

(2) R/W BL is set to “High”

(3) Read_WL is set to OFF (Transistor T1 is set to “Ground”)

What follows Looking now at FIGS. 5 and 7 collectively, in contrast to the operation of the conventional 1T1MTJ MRAM cell described above, the following are exemplary read and write cycles for the disclosed 2T1 MTJ (having 1W2R) memory cell 700.

### Read Cycle (Optional Between Port A and Port B):

(A) Read cycle, Port A:

(1) Read_WL_{A} is set to “High” (Transistor T1 is set to ON)

(2) R/W Line is set to “Lo” (ground)

(3) BL_{A} is set to ON with a voltage (0.3V˜1.2V)

(4) Sense amplifier SA_A connected to BL_{A} senses resistance of MTJ for data read.

### (B) Read Cycle, Port B:

(1) Read_WL_{B} is set to “High” (Transistor T2 is set to ON)

(2) R/W Line is set to “Lo” (Ground)

(3) BL_{B} is set to ON with a voltage (0.3V˜1.2V)

(4) Sense amplifier SA_B connected to BL_{B} senses resistance of MTJ for data read.

### Write (Program) Cycle:

(1) Write_WL is set to “High”

(2) R/W Line is set to “High”

(3) Read_WLA and Read_WLB set to OFF (Transistors T1 & T2 set to OFF)

What follows A non-volatile memory cell constructed according to the disclosed principles achieves both high speed and high efficiency in cell operation over conventional memory cells because of the dual-port reading capability. The disclosed cell provides a 2× operational bandwidth, rather than the 1× bandwidth available with a conventional cell structure. Of course, nothing limits the disclosed principles to only two, and any number of read ports may be constructed using the disclosed principles. These achievements are also obtained without significant penalties in cell area, power, or complexity. For example, exemplary cells have the smallest active power in each bank (or section) during a read cycle. This is due to the disclosed novel cell structure, which will only allow the read column being employed in a read operation to have a current path to V_{SS} (i.e., note the single R/W Line employed in all embodiments, while two sets of read bitlines are employed). This is the case even if all of the bits are precharged to a high state. In each operation cycle of the memory cell, 2× data output (read cycle) is available. Additionally, the disclosed cell provides for one read and one write operation, or even two data write operation options in each bank.

Moreover, the multiple read ports disclosed herein may also be employed simultaneously, rather than reading only one port at a time during device operation. Looking back at FIG. 6, such capabilities are possible because two distinct decoder circuits (not illustrated) may be employed, each for one set of read wordlines. As such, two distinct address control signals are provided via the corresponding sets of read wordlines. Still further, even further efficiency is provided if each memory cell is constructed with its own set or sets of “high” and “low” reference bits for reading and detecting the resistance state of the resistance-variable element. Furthermore, multiple sets of references bits may also be provided, if desired.

While various embodiments in accordance with the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages. As used in this disclosure, the term “signal” means a current and/or a voltage potential. As is understood by a person of ordinary skill in the art, a signal that is represented by a current may equivalently be represented by a voltage potential in an equivalent circuit. Thus, equivalent circuits of sense amplifiers employing current and/or voltage amplifiers may be employed to perform a similar function to the circuits described above.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein

What is claimed is:

1. A multiple read-port resistance-variable memory cell structure, comprising:
a resistance-variable element comprising:
conductive first and second electrodes, and
a resistance-variable structure between the electrodes and capable of being switched between a high resistance state and a low resistance state;
a first conductor electrically coupled to the first electrode and laying in a first direction;
at least two second conductors electrically coupled from the second electrode to at least one sensing device for sensing a resistance of the resistance-variable element;
at least two switching elements electrically coupled between corresponding ones of the second conductors and the at least one sensing device; and
at least two third conductors coupled to and configured to activate corresponding ones of the at least two switching elements to switch the resistance-variable element between the high and low resistance states.

2. A memory cell structure according to claim 1, wherein the resistance-variable element is a magnetic random access memory (MRAM) element and the resistance-variable structure comprises a magnetic tunneling junction stack including a free ferromagnetic layer, a pinned ferromagnetic layer, and an insulating tunneling barrier located therebetween.

3. A memory cell structure according to claim 2, further comprising a fourth conductor laying in a second direction and located proximate to the magnetic tunneling junction stack, the fourth conductor configured to provide a magnetic field proximate to the stack sufficient to switch a resistance of the stack between the high and low resistive states when another magnetic field is provided to the stack by the first conductor.

4. A memory cell structure according to claim 3, wherein the second direction is orthogonal to the first direction.

5. A memory cell structure according to claim 3, wherein the at least two switching elements are metal-oxide-semiconductor transistors, wherein either source or drain nodes of the at least two transistors are coupled to the second electrode and the others of the source or drain nodes of the at least two transistors are coupled to the at least one sensing device, and wherein the at least two third conductors are coupled to corresponding gates of the transistors.

6. A memory cell structure according to claim 1, wherein the at least two second conductors are laying in the first direction.

7. A memory cell structure according to claim 1, wherein the at least two third conductors are laying in a second direction orthogonal to the first direction.

8. A memory cell structure according to claim 1, wherein the resistance-variable element is a phase-change random access memory (PRAM) element and the resistance-variable structure comprises a heater layer and a chalcogen element located between the first and second electrodes.

9. A memory cell structure according to claim 8, wherein the at least two switching elements are metal-oxide-semiconductor transistors, wherein either source or drain nodes of the at least two transistors are coupled to the second electrode and the others of the source or drain nodes of the at least two transistors are coupled to the at least one sensing device, and wherein the at least two third conductors are coupled to corresponding gates of the transistors.

10. A memory cell structure according to claim 8, wherein the first and second electrodes comprise metal electrodes.

11. A memory cell structure according to claim 8, wherein the chalcogen element comprises a chalcogen material selected from the group consisting of Te, Se, Ge, Sb, Bi, Pb, Sn, As, S, Si, P, O, and any mixture or any alloy thereof.

12. A multiple read-port resistance-variable memory cell structure, comprising:
a magnetic random access memory (MRAM) element comprising:
conductive first and second electrodes, and
a magnetic tunneling junction stack having a free ferromagnetic layer, a pinned ferromagnetic layer, and an insulating tunneling barrier located between the electrodes and capable of being switched between a high resistance state and a low resistance state;
a first conductor electrically coupled to the first electrode and laying in a first direction;
at least two second conductors laying in the first direction and electrically coupled from the second electrode to at least one sensing device for sensing a resistance of the resistance-variable element;
at least two transistors wherein either source or drain nodes of the at least two transistors are coupled to the second electrode and the others of the source or drain nodes of the at least two transistors are coupled to the at least one sensing device, and wherein the at least two third conductors are coupled to corresponding gates of the transistors;
at least two third conductors laying in a second direction orthogonal to the first direction, and electrically coupled to and configured to activate corresponding ones of the at least two switching elements to switch the resistance-variable element between the high and low resistance states; and
a fourth conductor laying in the second direction and located proximate to the magnetic tunneling junction stack, the fourth conductor configured to provide a magnetic field proximate to the stack sufficient to switch a resistance of the stack between the high and low resistive states when another magnetic field is provided to the stack by the first conductor.

13. A method for sensing a resistance state of a resistive-variable memory cell, having a resistance-variable element comprising first and second electrodes and a resistance-variable structure between the electrodes capable of being switched between a high resistance state and a low resistance state, the method comprising:
providing a read signal to a first conductor electrically coupled to the first electrode and laying in a first direction;
providing a corresponding activation signal to at least one of at least two switching elements electrically coupled between corresponding at least two second conductors that are coupled to the second electrode and at least one sensing device; and
detecting the resistance state of the resistance-variable element with the at least one sensing device based on the read signal passing through the resistance-variable element, through a corresponding second conductor, and through the activated at least one switching element.

14. A method according to claim 13, wherein the detecting further comprises receiving at least a portion of the read signal in the sensing device and comparing the at least a portion to reference signals, the sensing device generating a digital output based on the comparison that represents the resistance state of the resistance-variable element.

15. A method according to claim 13, wherein providing an activation signal to at least one of at least two switching elements comprises providing an activation signal to all of the at least two switching elements simultaneously, and wherein the detecting comprises detecting the resistance state of the resistance-variable element with at least two sensing devices based on the read signal passing through the resistance-variable element and the activated switching elements.

16. A method according to claim 14, wherein the at least two second conductors are laying in the first direction.

17. A method according to claim 14, wherein the providing further comprises providing a corresponding activation signal to at least one of at least two switching elements via corresponding at least two third conductors laying in a second direction orthogonal to the first direction.

18. A method according to claim 14, wherein the resistance-variable element is a magnetic random access memory (MRAM) element and the resistance-variable structure comprises a magnetic tunneling junction stack including a free ferromagnetic layer, a pinned ferromagnetic layer, and an insulating tunneling barrier located therebetween.

19. A method according to claim 14, wherein the resistance-variable element is a phase-change random access memory (PRAM) element and the resistance-variable structure comprises a heater layer and a chalcogen element located between the first and second electrodes.

20. A method according to claim 19, wherein the at least two switching elements are metal-oxide-semiconductor transistors, wherein either source or drain nodes of the at least two transistors are coupled to the second electrode and the others of the source or drain nodes of the at least two transistors are coupled to the at least one sensing device, and wherein the at least two third conductors are coupled to corresponding gates of the transistors to provide the activation signals.
